(19) United States
(12) Patent Application Publication
(10) Pub. No.: US 2007/0082279 A1
(43) Pub. Date: Apr. 12, 2007

(54) Near-field exposure method and device manufacturing method using the same

(75) Inventors: Natsuhiko Mizutani, Tokyo (JP); Ryo Kuroda, Kanagawa-ken (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 10/554,994

(22) PCT Filed: Jun. 30, 2005
(86) PCT No.: PCT/JP05/12528

§ 371 Date: Dec. 20, 2006

(30) Foreign Application Priority Data
Jun. 30, 2004 (JP) 2004-194820

(51) Int. Cl. G03F 7/20

(52) U.S. Cl. 430/30; 430/311

(57) ABSTRACT

Disclosed is a near-field exposure method including a process of bringing a light blocking film with a plurality of small openings each having an opening width not greater than a wavelength of exposure light, into close contact with a photoresist layer provided on a surface of a substrate, and a process of projecting exposure light from an exposure light source to the light blocking film to transfer an opening pattern of the light blocking film to the photoresist layer, wherein, on the basis of a correlation between (a) a distance from a node of a standing wave to be produced in the photoresist layer to the light blocking film and (b) a light intensity distribution of near-field light to be produced in the photoresist layer adjacent the light blocking film, the distance from the standing wave node to the light blocking film is determined so as to provide a desired light intensity distribution.

### TECHNICAL FIELD

This invention relates to a near-field exposure method and a device manufacturing method using the same.

### BACKGROUND ART

Enlarging capacity of semiconductor memories and increasing speed and density of CPUs necessitates further reduction in processing size of optical lithography. Generally, the processing limits of microprocessing based on an optical lithographic apparatus are about the wavelength of a light source. Hence, the wavelength of a light source in optical lithographic apparatuses has been shortened, as by using near ultraviolet radiation laser, for example. Currently, microprocessing of a size of about 0.1 μm is being realized.

Here, in order to perform microprocessing of a size of 0.1 μm or under by use of optical lithographic apparatuses, the wavelength of the light source has to be shortened further, and there are many problems to be solved in relation to such extraordinarily short wavelength region, such as lens development, for example.

Another attempt to enabling microprocessing by use of optical lithographic apparatuses, separate from the movement toward the wavelength shortening, is a near-field exposure method.

U.S. Pat. No. 6,171,730 discloses a method in which a photomask having a pattern arranged to produce near-field light leaking or escaping from small openings formed in a light blocking film is closely contacted to a photoresist applied onto a substrate to expose the photoresist, whereby the pattern of the photomask is transferred to the photoresist. However, this patent document mentions nothing about adjustment of light intensity distribution adjacent the light blocking film.

Japanese Laid-Open Patent Application, Publication No. 2001-356486 discloses an exposure method wherein, for production of a structural member having fine surface step heights, the thickness of a resist layer closely contacted to an exposure mask is adjusted appropriately and the exposure is carried out on the basis of evanescent waves.

In the exposure method according to this patent document, however, if near-field exposure is carried out by use of a photomask having plural fine openings, there is a possibility of dispersion of the intensity distribution of near-field light. Particularly, among plural fine openings, the intensity distribution at a fine opening positioned at an outermost end may become low.

### DISCLOSURE OF THE INVENTION

It is accordingly an object of the present invention to provide a near-field exposure method by which, in the near-field exposure, the intensity distribution of near-field light can be corrected appropriately.

It is another object of the present invention to provide a device manufacturing method using such near-field exposure method.

In accordance with an aspect of the present invention, to achieve at least one of the above objects, there is provided a near-field exposure method including a process of bringing a light blocking film with a plurality of small openings each having an opening width not greater than a wavelength of exposure light, into close contact with a photoresist layer provided on a surface of a substrate, and a process of projecting exposure light from an exposure light source to the light blocking film to transfer an opening pattern of the light blocking film to the photoresist layer, wherein, on the basis of a correlation between (a) a distance from a node of a standing wave to be produced in the photoresist layer to the light blocking film and (b) a light intensity distribution of near-field light to be produced in the photoresist layer adjacent the light blocking film, the distance from the standing wave node to the light blocking film is determined so as to provide a desired light intensity distribution.

In accordance with another aspect of the present invention, there is provided a near-field exposure method including a process of bringing a light blocking film with a plurality of small openings each having an opening width not greater than a wavelength of exposure light, into close contact with a photoresist layer provided on a surface of a substrate, and a process of projecting exposure light from an exposure light source to the light blocking film to transfer an opening pattern of the light blocking film to the photoresist layer, wherein, in regard to interference light provided by near-field light escaping from the small openings into the photoresist and light emitted from the small openings into the photoresist and reflected by the surface of the substrate, a phase relation between the near-field light and the reflection light is adjusted so as to make a contrast of light intensity distribution adjacent the light blocking film, with respect to a direction along the exposure mask surface, into a desired shape, such that an opening pattern of the photomask is transferred to the photoresist on the basis of the light intensity distribution.

Briefly, in accordance with the present invention, an appropriate light intensity distribution can be produced adjacent the light blocking film and, thus, an optical latent image of desired shape can be provided.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1A is a plan view showing the structure of a known type photomask.

FIG. 1B is a longitudinal section of a know type photomask, being mounted to a support member.

FIG. 2 is a schematic view of a general structure of an exposure apparatus.

FIGS. 3A-3D are schematic views, respectively, for explaining the process of forming a resist pattern in accordance with a dual-layer resist method.

FIG. 4 is a schematic illustration for explaining the relation between the resist thickness and the shape of optical latent image.

### BEST MODE FOR PRACTICING THE INVENTION

Preferred embodiments of the present invention will now be described with reference to the attached drawings. In the drawings, like reference numerals are assigned to similar structural portions or functions, and duplicate description of them is omitted appropriately.

[Embodiment 1]

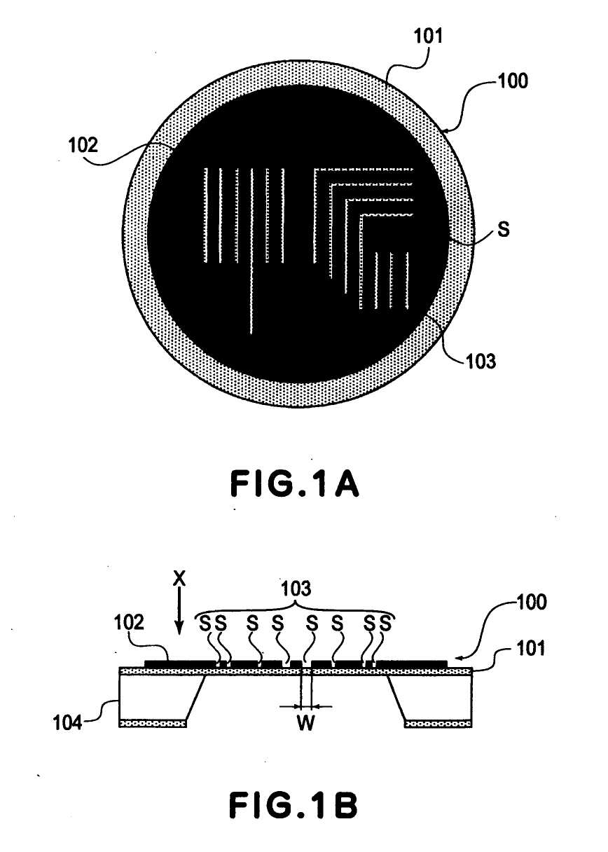

FIGS. 1A and 1B show a known type photomask (exposure mask) 100 for a near-field one-shot exposure process. Specifically, FIG. 1A is a plan view of the photomask 100 as viewed from the front surface side (in a direction of an arrow X in FIG. 1B). FIG. 1B is a longitudinal section of the photomask 100 being mounted to a supporting member 104, the section being taken along the thickness direction thereof.

As shown in these drawings, the photomask 100 comprises a mask base material 101 and a light blocking film 102 provided on the mask base material 101 (on the front surface thereof).

The mask base material 101 has a thickness T of 0.1-100 μm, and it is made of a material such as SiN, SiO₂ or SiC, for example, having large transmittance with respect to exposure light (to be described later).

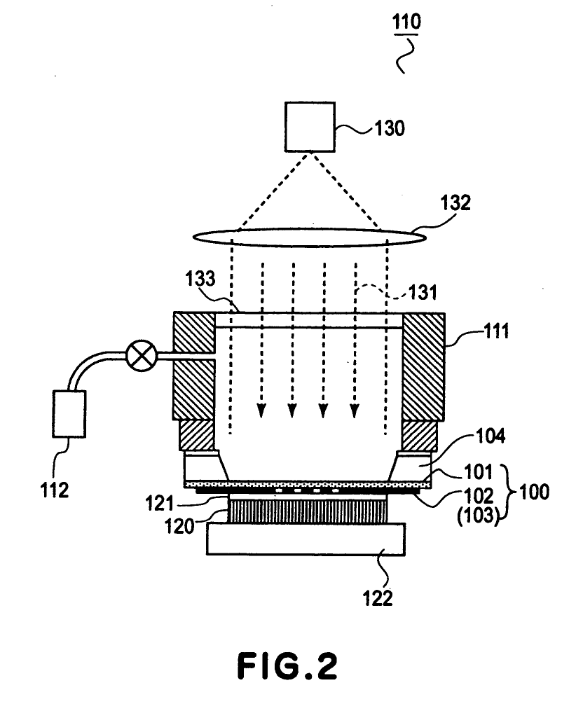

On the other hand, the light blocking film 102 has a thickness t, and it is made of a material such as a metal material of Cr, Al, Au or Ta, for example, having small transmittance with respect to the exposure light. Formed on this light blocking film 102 is an opening pattern (small-opening group) 103 consisting of a plurality of small openings. As best seen in FIG. 1A, each small opening is defined by a slit s of rectangular shape, for example, as viewed from the front surface side. As shown in FIG. 1B, each slit s extends through the light blocking film 102 from its front surface side to its back surface side. The slit s has an opening width w which is made not greater than the wavelength of exposure light to be produced from an exposure light source (Hg lamp 130 in FIG. 2), and the opening length of the slit is made sufficient long as compared with its opening width w. Such opening pattern 103 can be produced in accordance with a direct processing method using a focusing ion beam or a scanning probe processing machine, a lithographic method for processing a resist film on the basis of electron lithography or X-ray lithography, a micropattern forming method based on nanoimprint method or near-field exposure method, for example.

Generally thin-film like photomask 100 as described above is supported by the support member 104. The support member 104 has a structure as shown in FIG. 1B, and it supports the outer peripheral portion of the mask base material 101. The portion of the light blocking film 102 where the opening pattern 103 is formed, corresponds to the void of the supporting member 104.

This photomask 100 is going to be brought into close contact with a thin-film like photoresist applied to a substrate (to be described later) and, by projecting light thereto in a direction perpendicular to it, the pattern is lithographically printed on the photoresist.

More specifically, with the light projected onto the photomask 100, a light intensity distribution provided thereby within the photoresist produces an optical latent image in the photoresist. By performing an appropriate developing process to the photoresist, a photoresist pattern corresponding to this optical latent image is obtainable.

Referring to FIG. 2, an exposure apparatus 110 into which a photomask 100 such as described above is incorporated, will be explained. The exposure apparatus 110 is arranged to hold the photomask 100 and to transfer the pattern thereof onto a substrate having a photoresist applied thereto.

As shown in FIG. 2, the photomask 100 for near-field exposure is mounted to the bottom of a pressure adjusting container 111 through the supporting member 104 with its front surface facing down, that is, with the mask base material 101 positioned upwardly and the light blocking film 102 positioned downwardly. In other words, the photomask 100 is disposed with its front surface (lower surface as viewed in the drawing) placed outside the pressure adjusting container 111 and with its rear surface (upper surface in the drawing) facing to the pressure adjusting container 111. The inside pressure of the pressure adjusting container 111 can be adjusted by use of pressure adjusting means 112.

As regards an article to be exposed, a substrate 120 having a resist film (photoresist) 121 formed on its surface is used. The substrate 120 is mounted on a stage 122. By moving the stage 308 along an X-Y plane, relative alignment of the substrate 120 with the photomask 100 with respect to two-dimensional directions along the mask surface is carried out. Then, the stage 122 is driven in a direction of a normal to the mask surface (i.e., upward/downward direction as viewed in the drawing), to bring the photomask into intimate contact with the resist film 121 on the substrate 120.

By adjusting the inside pressure of the pressure adjusting container 111 through the pressure adjusting means 112, the surface of the photomask 100 and the resist film 121 on the substrate 120 are brought into close contact with each other so that, throughout the whole surface the clearance between them becomes equal to 100 nm or under.

Thereafter, exposure light 131 emitted from an Hg lamp (exposure light source) 130 and transformed by a collimator lens 132 into parallel light, is introduced into the pressure adjusting container 111 through a glass window 133, such that the exposure light is projected onto the photomask 100 from its back side. In response to this illumination, near field is produced adjacent the slits at the front side of the photomask 100, by which exposure of the resist film 121 is carried out.

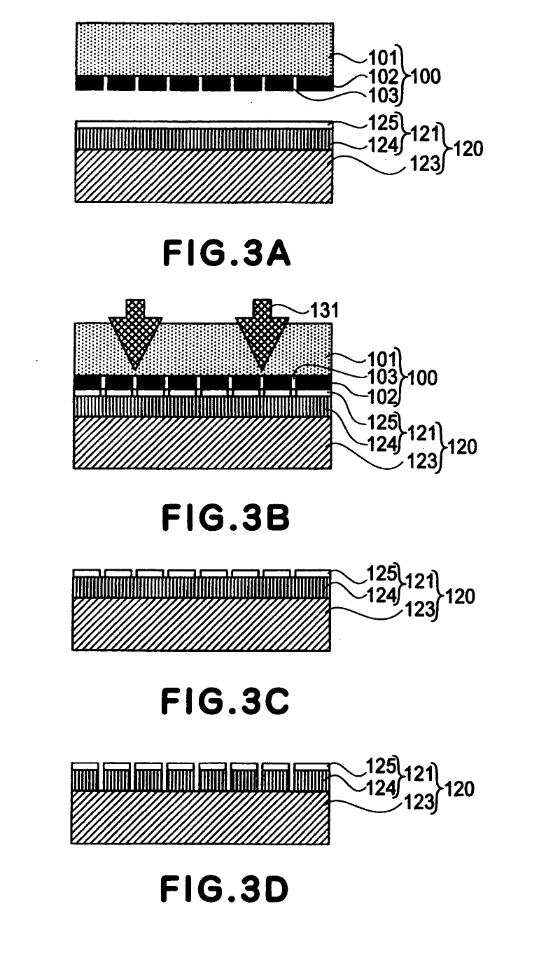

FIGS. 3A-3D illustrate a pattern forming method according to this embodiment, including one buffering layer. This method is called“dual-layer resist method”. FIG. 3A shows a photomask 100 and a substrate 120 which is an object to be exposed. As described hereinbefore, the photomask 100 comprises a mask base material 101 and a light blocking film 102 having an opening pattern 103. The substrate 120 was produced as follows.

First, an Si substrate was coated with a negative type photoresist by using a spin coater. Then, it was hard baked to provide a first layer, that is, a lower layer resist (versatile resist: buffering layer) 124. The lower layer resist 124 had a 180 nm thickness. By this heating process, the photosensitivity of the lower layer resist 124 is gone.

Subsequently, an Si containing positive type resist (e.g.,“FH-SP3CL” available from Fuji Film Arch Inc.) was applied onto the lower layer resist 124 and, after that, it was prebaked to provide a second layer, that is, an upper layer resist 125. The upper layer resist 125 had a 20 nm thickness, and a photoresist layer having dual layer structure was produced in this manner.

The Si substrate 123 having a photoresist layer of dual-layer structure and the photomask 100 were approximated to each other by the exposure apparatus 110 shown in FIG. 2 as described, and a pressure was applied to bring the upper layer resist 125 and the photomask 100 into close contact with each other. Then, exposure light 131 was projected through the photomask 100, and the pattern of the photomask 100 was printed on the upper layer resist 125 (FIG. 3B). After that, the photomask 100 was disengaged from the upper layer resist 125 surface, and development of the upper layer resist 125 as wall as postbake were carried out, whereby the pattern of the photomask 100 was transferred as a resist pattern (FIG. 3C).

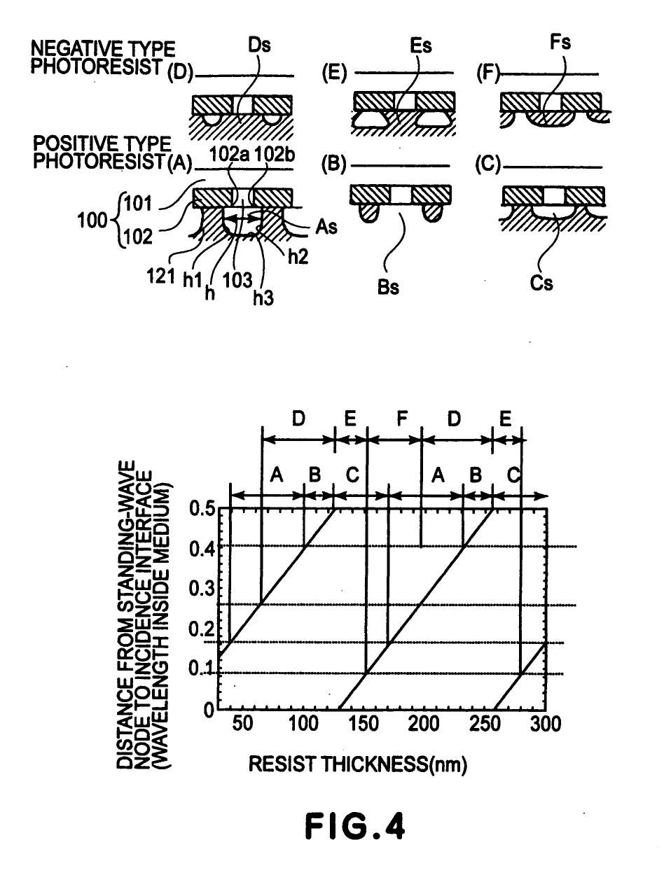

Since the sum of the film thicknesses of the dual photoresist layers came to 200 nm, as shown in FIG. 4, as an upper-layer resist pattern of an optical latent image having almost perpendicular side walls, a pattern having good perpendicularity and good dimensional precision was produced.

Subsequently, by means of oxygen reactive ion etching using the pattern defined by the upper layer resist 125 as an etching mask, the lower layer 124 (first layer) was etched (FIG. 3D). The oxygen reactive ion etching has a function for oxidizing Si contained in the upper layer resist 125 to thereby improve the etching resistance of that layer.

With the procedure described above, various patterns of the photomask 100 can be transferred onto the substrate 120 as a resist pattern having high aspect ratio and with uniformed size.

Here, if a resist pattern formed in the upper layer resist 125 is used for forming a pattern on the lower layer resist 124, the size at the bottom of an opening defined in the upper layer resist 125 is the most important quantity. In that case, when the electric field strength adjacent the interface between the upper and lower layers changes sharply, a resist pattern less changing in size is obtainable.

Also, where such resist pattern is directly used as an etching mask for the substrate 120 which is a backing substrate, if the side wall has good perpendicularity, the dimensional precision of a transferred pattern can be improved. On the other hand, where a metal film is formed on a produced resist pattern to produce a diffractive optical element or an optical element of sub-wavelength size, there may be cases wherein a sinewave-like resist pattern changing slowly in shape in accordance with the device design is preferred.

In order to obtain a resist pattern having a desired sectional shape corresponding to the purpose as exemplified here, in addition to choosing exposure and development process conditions appropriately, controlling the light intensity distribution within the photoresist layer 121 in the exposure process is also effective.

Particularly, in the near-field exposure, various resist profiles are obtainable by controlling the light intensity distribution in the thickness direction of the photoresist layer 121.

This is because, while propagating light can be described almost as plane waves and it does not change sharply with respect to the thickness direction of the photoresist layer 121, the near-field light leaking or escaping from the slit (small opening) has a light intensity distribution that depends on the distance from the slit. This is a large difference to a projection exposure method in which an optical image is formed by use of propagating light.

By the way, when the photomask 100 is closely contacted to the photoresist layer 121 as described above and light is projected thereto, near-field light is produced in the vicinity of the slit opening. At the same time, within the photoresist layer, standing waves are produced due to interference of downwardly propagating light and upwardly propagating light.

These standing waves are produced as a result that the propagating light component of light leaking from the opening is reflected by the photoresist/substrate interface and the photoresist/light-blocking-film interface, respectively. Here, the amplitude reflectances at these interfaces are taken as r1 and r2. Also, the amplitude reflectance at the photoresist/opening interface as can be defined with respect to the refractive index of the opening of the light blocking film (usually it is an air or vacuum and the refractive index is 1) is taken as rv.

Since the energy of propagating light is applied from the light blocking film side, the state of standing waves will now be considered on an assumption that the plane waves (propagating light) are propagated through the photoresist from the photoresist/light-blocking-film interface (now denoted by z=0) toward the photoresist/substrate interface (now denoted by z=L) along the Z-axis direction.

The complex field intensity E(z) of the standing waves is expressed by:
E(z)=(exp(ikz)+r1exp[−ikz]*exp[2ikL])/(1−r1r2exp(2ikL)) (a)
where k=nω/c is the wavenumber of light having an angular frequency ω, and n is the refractive index of the photoresist.

Here, the influence of the opening at the photoresist/light-blocking-film interface can be considered by replacing r2 in equation (a) by rv. Actually this replacement was done, but no particular change occurred in the positions of the node and antinode of the obtained standing wave distribution.

It is seen that the sanding wave distribution depends on the reflectance r1 at the photoresist/substrate interface as well as the refractive index of the photoresist contingent to the thickness L of the photoresist layer 121 and the wavenumber k. Furthermore, it is seen that the reflectance r1 at the photoresist/substrate interface can be adjusted by providing a refractive index controlling layer on the topmost layer of the substrate 120 and by controlling the refractive index and the thickness of this layer. In that case, what resulting from combining the substrate 121 and the refractive index controlling layer provided thereon will correspond to the “substrate” having been described above.

As has been explained above, in order to discuss the light intensity distribution within the thin film photoresist layer 121, that is, the shape of an optical latent image therein, while taking into account the standing waves and near-field light produced from the slit opening, it would be effective to perform numerical analysis using a vector electromagnetic field analysis method.

The inventors have analyzed the shape of this optical latent image in accordance with a finite differential time domain method (FDTD method) which is one of vector electromagnetic field analysis methods.

The calculations were done under the following conditions. The mask base material 101 was made of SiN having a refractive index 1.9, and as the light blocking film 102, a Cr film of a thickness of 50 nm was formed on the surface of the mask base material 101. The light blocking film 102 was formed with slits (small openings). The photomask 100 thus produced was brought into intimate contact with a photoresist layer 121 upon an Si substrate 123. The calculations were done taking the wavelength of exposure light as g-line of 436 nm in vacuum. The calculations were done with respect to an example wherein the pattern comprised slits having an opening width 40 nm and being repeated at a pitch p=100 nm.

From the results of analysis, the following features were found.

(1) As regards the shape of an optical latent image produced in the photoresist layer 121, in each of a case where a negative type resist is used and a case where a positive type resist is used, the shape can be roughly classified into three types. In FIG. 4, schematic illustrations at (A), (B) and (C) are three types of shapes of optical latent images when a positive type resist is used, and schematic illustration at (D), (E) and (F) are three types of shapes of optical latent images when a negative type resist is used. In these illustrations at (A)-(F) in FIG. 4, those regions depicted by hatching of lines tilted upper right correspond to the portions where the photoresist layer 121 is present, that is, non-fused portions of the photoresist layer 121. These portions correspond to the resist pattern as finished. On the other hand, those regions depicted by hatching of lines tilted upper left correspond to portions where the light blocking film 102 is present.

(2) The shapes of these optical latent images have a strong relation with the distribution of standing waves produced in the photoresist layer 121. More specifically, in the standing wave distribution as expressed by equation (a) above, the distance from the node to the incidence interface (photoresist/light-blocking-film interface) is an intensely dominant parameter in the light intensity distribution.

Here, as regards the shape of the optical latent image, when plane waves having an amplitude 1 within the upper mask base material 101 at the light blocking film 102 side of the photomask 100 illuminate the light blocking film 102, the shape can be depicted by isointensity lines in regard to the light intensity inside the photoresist layer 121. With regard to the light intensity that defines the optical latent image, in many cases it is chosen out of a range approximately from 0.05 to 2. Typically, where an adequate strength chosen out of 0.1 to 1 is taken as the size of optical latent image, in many cases good correspondence is obtainable with the results of actual processes.

In those regions closer to the opening than the isointensity line, the light intensity of near field is strong, while in those regions far from the opening than the isointensity line, the light intensity of near field is weak.

Referring to illustrations at (A)-(F) in FIG. 4, the shape of optical latent image will be explained in greater detail.

Between a case where a positive type photoresist is used as the photoresist layer 121 and a case where a negative type photoresist is used therefor, the strength that can provide a practical latent image shape might be slightly different. This is because if a negative type photoresist is used, a somewhat larger exposure amount is set so that portions to be unfused as a result of exposure define a mutually connected shape. Namely, regarding the value of strength of the isointensity line to be chosen out of the calculation results, a somewhat smaller one may be selected.

First, the latent image distribution premised on use of a positive type photoresist will be considered. Hereinafter, the width h of the latent image refers to the width of a blank (void) in the drawing, that is, the width of the region where the light intensity is stronger.

The optical latent image As at (A) in FIG. 4 begins to exist from a position retreated by about 10 nm from the edge 102a or 102b of the light blocking portion. The optical latent image As reaches to a depth of about 10-40 nm, from the light blocking portion, and the side wall portions h1 and h2 have a shape of good perpendicularity. The bottom h3 of the optical latent image As is connected to the side walls h1 and h2, extending downwardly from about the edges 102a and 102b of the light blocking film 102. The width h of the optical latent image As does not change much with the depth. In the following description related to illustrations (B)-(F) of FIG. 4, reference numerals or characters will be omitted.

The shape of the optical latent image Bs at (B) in FIG. 4 begins to exist from a position retreated by about 10 nm from the edge of the light blocking portion, like that of (A). The side wall portion of the optical latent image Bs extends into the photoresist while drawing a gentle arcuate shape, but this boundary line returns to about the opposite-side edge of the same light blocking portion without being extended to just underneath the opening. The width of the optical latent image Bs monotonously increases with the depth in the photoresist.

The shape of the optical latent image Cs at (C) in FIG. 4 begins to exist from a position retreated by about 20 nm from the edge of the light blocking portion. The width at the upper portion of the optical latent image Cs is made much larger than the width of the opening of the light blocking film. Extending from here deeply into the photoresist, it gradually comes close to underneath the opening and, just underneath the opening, the depth becomes largest. Namely, the width of the optical latent image Cs comes narrower with the depth. Then, under an adjacent light blocking portion, it comes back to the photoresist surface.

The optical latent images at (C) differs from (A) in that the side wall portion of the optical latent image Cs includes a gentle slant and that the size of the optical latent image Cs decreases within the photoresist with the depth.

The boundary of shape of the optical latent images As, Bs and Cs at (A), (B) and (C) in FIG. 4 generally show those tendencies such as described above, although it might be influenced to some degree by exposure and development conditions, namely, by selection of the intensity to be chosen as the boundary line of the optical latent image. Taking this influence into account, the boundary line that defines the latent image shape in FIG. 4 would have an error of about ±15 nm.

Next, the latent image distribution premised on use of a negative type photoresist will be considered. Here, the width of optical latent images Ds, Es and Fs refers to the width of the region depicted by hatching of lines tilted upper right, namely, the width of a region where the light intensity is stronger.

The optical latent image Ds at (D) in FIG. 4 extends from the edge of the light blocking portion to the opposite side of the same light blocking portion, without being extended across the opening. The width of the optical latent image produced in the photoresist increases monotonously with the depth.

The optical latent image Es at (E) in FIG. 4 is similar to the optical latent image Ds at (D) in that it does not extend across the opening, but there is a region where the width of the optical latent image Es becomes narrower with the depth within the photoresist.

The optical latent image Fs at (F) in FIG. 4 begins to exist from underneath the light blocking portion, and it extends across the opening to under an adjacent light blocking portion. The shape is relatively gentle.

Although it may not be easy to produce a resist pattern by using the optical latent image Ds, Es or Fs at (B) to (F) applied to a single layer photoresist, if it is combined with a surface imaging method such as a dual-layer resist method, the optical latent images Ds, Es and Fs at (B) to (F) may be used.

Out of these latent image shapes, one latent image shape corresponding to individual process or purpose may be chosen. To this end, the resist film thickness corresponding to a desired light intensity distribution as well as the film thickness and refractive index of a refractive index controlling layer, constituting the substrate, may be chosen. For the selection, equation (a) may be referred to as a specific index of selection, and the node of standing wave distribution and the distance to the resist/light-blocking-film interface may be chosen. By this, an index is obtainable easily.

The graph at the lower half of FIG. 4 shows the distance from the node of standing waves to the incidence interface, for obtaining the optical latent images As-Fs of (A) to (F) described above. In this graph, the resist thickness (nm) is taken on the axis of abscissa, and the distance from the standing wave node to the incidence interface is taken on the axis of ordinate. It is seen from the graph that once the resist thickness is fixed, the distance from the standing wave node to the incidence interface is determined automatically and, at the same time, the shape of optical latent image in the positive type photoresist is determined, one out of (A) to (C). Similarly, where a negative type photoresist is used, the shape of optical latent image is determined, one out of (D) to (F). To the contrary, if the shape of optical latent image is fixed, the resist thickness for accomplishing that shape can be determined. It is to be note here that the resist thickness that provides a certain shape of optical latent image is repeated periodically in accordance with the wavelength of standing waves.

For example, where the shape of optical latent image As at (A) is desired in relation to a positive type resist and if the wavelength of standing waves is λR, from FIG. 4 it would be understood that selection should be made so that the distance from the standing wave node to the light blocking film comes into a range from 0.16 λR to 0.4 λR. When such shape is chosen, particularly, intensity distribution of near-field light that reaches up to a deep portion inside the photoresist can be provided.

The method of controlling the contrast in a direction along the photomask surface, with respect to the intensity distribution adjacent the slit opening described above, can be explained also from the point of interference between near-field light escaping from the opening of the light blocking film of the photomask and reflected light from the substrate.

As regards the near-field light leaking from the opening of a light blocking film of a photomask, a portion of the near-field light is transformed within the photoresist into propagating light. The propagating light is in turn reflected by the interface with the substrate, into an opposite direction, such that it interfere with the near-field light adjacent the opening. The contrast in the mask surface direction of the light intensity distribution due to this interference increases within a desired photoresist adjacent the opening, only when the phase of the near-field light at that position and the phase of the reflected light are approximately registered with each other.

Here, when the refractive index of the photoresist is nr and the refractive index of the substrate is ns, if nr<ns, since the phase of the reflection light at the substrate surface is inverted, the condition for that the phases of the near-field light and reflected light in proximity to the opening are approximately registered with each other can be expressed, using the photoresist thickness L, the exposure light wavelength λ, and the wavelength λR within the photoresist, as follows:
nsxL≈(¼+m/2)xλ
where m=0, 1, 2, . . .
   Alternatively,
   L=(¼+m/2)xλR
where m=0, 1, 2, . . .

If on the other hand nr>ns, since the phase of the reflection light at the substrate surface is not inverted, the condition for that the phases of the near-field light and reflected light in proximity to the opening are approximately registered with each other can be expressed as follows:
nsxL≈(½+m/2)xλ
where m=0, 1, 2, . . .
   Alternatively,
   L=(½+m/2)xλR
where m=0, 1, 2, . . .

By controlling the phase relation between the near-field light escaping from the opening and the substrate reflection light in the manner described above, the contrast of the light intensity distribution adjacent the photomask, with regard to the direction along the photomask surface, can be controlled as desired.

In practice, in addition to the near-field light leaking from the opening and the reflected light from the substrate, light reflected by the photomask surface may interfere with the reflection light from the substrate, such that the above-described interference condition may slightly shift. This can be numerically analyzed, and the results obtainable thereby are what having been described with reference to FIG. 4.

Here, in order to increase the contrast of the light intensity distribution adjacent the photomask with respect to a direction along the photomask surface, it would be effective to enlarge the intensity of reflection light. To this end, if for example the substrate has low reflectance with respect to the exposure light, a high-reflectance layer made of metal, for example, may be provided on the substrate surface.

Where a buffering layer (lower resist layer as described hereinbefore) is provided between the photoresist and the substrate, as in the dual-layer resist method, L in the interference condition described above may be replaced by
nr*L+nb*L′
that represents the optical distance between the photoresist and the substrate, using the photoresist thickness L, the refractive index nr thereof, the buffering layer thickness L′ and the refractive index nb thereof.
[Embodiment 2]

Next, an example wherein a pattern is formed upon a substrate having a refractive index smaller than that of a photoresist, to produce an optical element on the basis of a gently-sloping resist shape, will be described.

The object to be exposed here comprised an SiO₂ substrate having a refractive index slightly smaller than that of a photoresist, and a Cr layer of 20 nm thickness formed on the SiO₂ substrate. Since the difference in refractive index at the interface between the photoresist and SiO₂ is small and the reflectance at that interface is not large, the Cr layer was interposed between them. Upon the Cr layer, a positive type photoresist, for example, Az7904, was applied to a thickness 150 nm.

The substrate to be exposed and the photomask were brought close to each other by the exposure apparatus 111 shown in FIG. 2 and, by applying a pressure, they were brought into close contact with each other. Then, exposure light was projected through the photomask to print the pattern of the photomask on the photoresist. Thereafter, the photomask was disengaged from the photoresist surface, and development and postbake of the photoresist were carried out, by which the pattern of the photomask was transferred as a resist pattern.

Through the selection of resist thickness, an optical latent image Cs shown at (C) in FIG. 4, that is, an optical latent image having gentle resist pattern profile, can be produced such that, by using this optical latent image, a similar resist pattern can be produced.

By forming a film of Au of 50 nm thickness upon the thus produced resist pattern, a reflection type diffraction grating can be produced. Thus, a diffraction grating which reflects a gentle-sloped resist pattern, that is, a diffraction grating having its corners rounded off, can be provided.

[Embodiment 3]

This is an example of resist patterning using a negative type photoresist, and it will be described to explain selection of resist thickness according to the type of a photoresist used.

The object to be exposed had the following structure. Namely, a negative type photoresist was applied onto an Si substrate by using a spin coater. The resist thickness was 100 nm.

The substrate to be exposed and the photomask were brought close to each other by the exposure apparatus 111 shown in FIG. 2 and, by applying a pressure, they were brought into close contact with each other. Then, exposure light was projected through the photomask to print the pattern of the photomask on the photoresist. Thereafter, the photomask was disengaged from the photoresist surface, and development and postbake of the photoresist were carried out, by which the pattern of the photomask was transferred as a resist pattern.

Although with this resist thickness the patterning of a positive type photoresist is difficult to achieve, in the case of negative type photoresist, a resist pattern can be produced with a depth of about 20 nm.

[Embodiment 4]

By using the near-field exposure method in which the near-field distribution adjacent the small openings are controlled specifically, the sectional shape of the resist pattern to be produced after exposure and development can be controlled. Thus, by transferring this resist pattern onto various substrates, structures of various shapes and sizes not greater than 100 nm can be produced.

Thus, in accordance with such microdevice manufacturing technology for a structure of a size of 100 nm or under, as described above, various specific devices can be produced. Examples are (1) a quantum dot laser device where the method is used for production of a structure in which GaAs quantum dots of 50 nm size are arrayed two-dimensionally at 50 nm intervals, (2) a sub wavelength element (SWS) structure having antireflection function where the method is used for production of a structure in which conical SiO₂ structures of 50 nm size are arrayed two-dimensionally at 50 nm intervals on a SiO₂ substrate, (3) a photonic crystal optics device or plasmon optical device where the method is used for production of a structure in which structures of 100 nm size, made of GaN or metal, are arrayed two-dimensionally and periodically at 100 nm intervals, (4) a biosensor or a micro-total analyzer system (μTAS) based on local plasmon resonance (LPR) or surface enhancement Raman spectrum (SERS) where the method is used for production of a structure in which Au fine particles of 50 nm size are arrayed two-dimensionally upon a plastic substrate at 50 nm intervals, (5) a nano-electromechanical system (NEMS) device such as SPM probe, for example, where the method is used for production of a radical structure of 50 nm size or under, to be used in a scanning probe microscope (SPM) such as a near-field optical microscope, an atomic force microscope, and a tunnel microscope, and the like.

While the invention has been described with reference to the structures disclosed herein, it is not confined to the details set forth and this application is intended to cover such modifications or changes as may come within the purposes of the improvements or the scope of the following claims.

1. In a near-field exposure method including a process of bringing a light blocking film with a plurality of small openings each having an opening width not greater than a wavelength of exposure light, into close contact with a photoresist layer provided on a surface of a substrate, and a process of projecting exposure light from an exposure light source to the light blocking film to transfer an opening pattern of the light blocking film to the photoresist layer, the improvements residing in that:
on the basis of a correlation between (a) a distance from a node of a standing wave to be produced in the photoresist layer to the light blocking film and (b) a light intensity distribution of near-field light to be produced in the photoresist layer adjacent the light blocking film, the distance from the standing wave node to the light blocking film is determined so as to provide a desired light intensity distribution.

2. A method according to claim 1, wherein the standing wave is produced on the basis of interference between (i) reflected light from an interface between the photoresist and the substrate and (ii) reflected light from an interface between the photoresist and the light blocking film.

3. A method according to claim 1, wherein, in order to determine the distance from the standing wave node to the light blocking film, at least one of a thickness of the photoresist layer, a refractive index of the photoresist layer, and the wavelength of the exposure light is adjusted.

4. A method according to claim 1, wherein the substrate comprises a laminated structure having a backing substrate and a refractive index controlling layer provided on the backing substrate.

5. A method according to claim 4, wherein, in order to determine the distance from the standing wave node to the light blocking film, at least one of a refractive index and a thickness of the refractive index controlling layer is adjusted.

6. A method according to claim 1, wherein the photoresist layer is provided by a positive type photoresist and wherein, where a wavelength of the standing wave inside the photoresist is λR, the distance from the standing wave node to the light blocking film is within a range of 0.16λR to 0.4λR.

7. In a near-field exposure method including a process of bringing a light blocking film with a plurality of small openings each having an opening width not greater than a wavelength of exposure light, into close contact with a photoresist layer provided on a surface of a substrate, and a process of projecting exposure light from an exposure light source to the light blocking film to transfer an opening pattern of the light blocking film to the photoresist layer, the improvements residing in that:
in regard to interference light provided by near-field light escaping from the small openings into the photoresist and light emitted from the small openings into the photoresist and reflected by the surface of the substrate, a phase relation between the near-field light and the reflection light is adjusted so as to make a contrast of light intensity distribution adjacent the light blocking film, with respect to a direction along the exposure mask surface, into a desired shape, such that an opening pattern of the photomask is transferred to the photoresist on the basis of the light intensity distribution.

8. A method according to claim 7, wherein the adjustment of the phase relation is carried out by adjusting an optical distance between an upper surface of the photoresist layer and the surface of the substrate.

9. A method according to claim 7 or 8, wherein, where a refractive index of a material contacted to the substrate surface is smaller than that of the substrate, the optical distance between the upper surface of the photoresist layer and the substrate surface is made approximately equal to (¼+m/2)xλR (where m=0, 1, 2, . . .), whereby the contrast of the light intensity distribution adjacent the light blocking film with respect to the direction along the exposure mask surface is enlarged.

10. A method according to claim 7 or 8, wherein, where a refractive index of a material contacted to the substrate surface is larger than that of the substrate, the optical distance between the upper surface of the photoresist layer and the substrate surface is made approximately equal to (½+m/2)xλR (where m=0, 1, 2, . . .), whereby the contrast of the light intensity distribution adjacent the light blocking film with respect to the direction along the exposure mask surface is enlarged.

11. A method according to any one of claims 7-10, wherein a high-reflectance layer is provided between the substrate and the photoresist layer.

12. A device manufacturing method including an exposure process based on a near-field exposure method as recited in claim 1 or 7.
